(19) United States
(12) Patent Application Publication
(10) Pub. No.: US 2007/0158710 A1
(43) Pub. Date: Jul. 12, 2007

(54) Low-noise image sensor and transistor for image sensor

(76) Inventors: Bong Ki Mheen, Daejeon (KR); Mi Jin Kim, Daejeon (KR); Young Joo Song, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/633,887

(22) Filed: Dec. 5, 2006

(30) Foreign Application Priority Data
Dec. 5, 2005 (KR) 10-2005-0117419
Sep. 11, 2006 (KR) 10-2006-0087439

(51) Int. Cl. H01L 31/113; H01L 31/062

(52) U.S. Cl. 257/291

(57) ABSTRACT

Provided are a low-noise image sensor capable of improving the efficiency of charge transfer from a photodiode to a diffusion node region and effectively suppressing the generation of dark current, and a transistor for the image sensor. The image sensor includes: a photosensitive pixel having a transfer transistor formed in a structure which causes hole accumulation in a part or all regions of a gate oxide; and a sensing control part applying a negative offset potential to the gate during a part or whole of a turn-off period of the transfer transistor. When the transfer transistor is off, the image sensor may form a sufficient barrier and accumulate electrons in the photodiode, and when the transistor is on, the sensor sufficiently lowers a barrier, fully depletes the photodiode before the transfer transistor reaches a threshold voltage, and inactivates a trap in a predetermined region for a certain time, and thus the dark current can be reduced.

### CROSS-REFERENCE TO RELATED APPLICATION

This application claims priority to and the benefit of Korean Patent Application Nos. 2005-117419, filed Dec. 5, 2005, and 2006-87439, filed Sept. 11, 2006, the disclosures of which are incorporated herein by reference in their entirety.

### BACKGROUND

1. Field of the Invention

The present invention relates to a low-noise image sensor and a transistor for the image sensor, and more particularly, to a low-noise image sensor capable of improving the efficiency of charge transfer from a photodiode to a diffusion node region and effectively suppressing the generation of dark current and enhancing well capacity, and a transistor for the image sensor.

2. Discussion of Related Art

Image sensors may be classified into a charge-coupled device (CCD) sensor and a CMOS image sensor, which basically utilize an electron-hole pair separated by light having a higher energy than a silicon bandgap. In image sensors, an amount of irradiated light is generally estimated by collecting electrons or holes.

Especially, the CMOS image sensors are integrated sensors having a block amplifying or processing signals using active devices, such as MOS or CMOS transistors, in a sensor chip. That is, since the CMOS image sensor has a photodiode and a transistor composed of a common CMOS device in each image pixel, a conventional CMOS process is utilized almost as it is. This allows an image signal processing and detecting unit integrated in an external block of pixel. Thus, the CMOS image sensor may overcome a shortcoming of the CCD that has to have such an image signal processing part in a separate chip, adapt various image sensor structures because of its integrated structure, and provide a method for various subsequent processes.

One of widely used CMOS image sensor structures is a structure comprising four transistors as illustrated in FIG. 1. In the above structure, a photodiode PD which is a light sensing unit and four NMOS transistors constitute one unit pixel. Among the four NMOS transistors, a transfer transistor Tx serves to transfer a photocharge generated in the photodiode PD to a diffusion node region FD, a reset transistor Rx serves to emit charges stored in the diffusion node region FD for signal detection, a drive transistor Dx serves as a source follower, and a switch transistor Sx serves to switch and address signals.

When the transfer transistor Tx is turned off and, in this state, light is irradiated onto a surface of the photodiode PD region, holes and electrons are separated, and the holes flow into a connected ground and are removed, and the electrons are accumulated in the photodiode PD region. The transfer transistor Tx functions as a transfer channel transferring the electrons accumulated in the photodiode PD region by light irradiation to a diffusion node 131 when a suitable voltage is applied to a gate 111 of the transfer transistor, and performs a reset function of completely removing electrons from the photodiode PD before the light is irradiated to the photodiode. The diffusion node 131 is formed by diffusion capacitance 114 and gate capacitance of the drive transistor Dx, and a voltage at the node is reset by the reset transistor Rx. That is, the voltage at the diffusion node 131 is reset immediately before the electrons are taken from the photodiode PD, or a reset voltage is applied to the diffusion node 131 to reset the photodiode PD region.

In order to obtain a two-dimensional image, a voltage is applied to a gate 141 of the switch transistor Sx to select one column. Particularly, one pixel is biased by one current source 150, which operates the drive transistor Dx and the switch transistor Sx so that a voltage value of the diffusion node 131 is read out to an output node 142.

The major characteristic of the pixel having the above structure is that a light receiving part, i.e., the photodiode PD region and a light-to-voltage conversion part, i.e., the diffusion node 131 are separated from each other, and a ratio of capacitance between the two parts may be used to excellently adjust sensitivity to light. That is, the sensitivity to light can be relatively adjusted by increasing the area of a detector, for example, the photodiode while keeping the capacitance of the diffusion node 131 constant.

FIG. 2 is a cross-sectional view of a device having a pixel formed in the above structure. Referring to FIG. 2, the photodiode PD region, the transfer transistor Tx, and the diffusion node 131 of the structure of FIG. 1 are shown, and other parts are omitted. The transfer transistor Tx comprises a gate 210, a gate oxide layer 220 and a p-type substrate 260, the photodiode PD region comprises a photodiode doped region 250 and a surface p-doped region 230, and the diffusion node 131 comprises an n+ diffusion node 240.

As described in U.S. Patent Publication No. 2005/0017155 A1 entitled “Active Pixel Cell using Negative to Positive Voltage Swing Transfer Transistor” by Manabe et al., reduction of a leakage current of the photodiode causing dark current may be accomplished by connecting a surface potential of the diode to a P well or a p-type substrate through a p+ layer. As a result, a surface voltage is forcibly made to be a complete ground potential by maintaining a lower potential than that in a p-doped region of a substrate, thereby eliminating a potential difference and suppressing the generation of the dark current.

In addition, the photodiode having such a structure needs to accommodate photoelectrons as much as possible in order to increase a size of a photo signal. That is, the number of electrons stored in the photodiode must be maximized. Here, the number of electrons is called well capacity. However, in general, increased capacity of the photodiode results in image lag caused by the incomplete transfer of charges. One of methods for increasing the photodiode capacity is to increase the voltage for complete depletion of photodiode, namely, a pinning voltage. However, this may cause the incomplete transfer of charges.

As disclosed in IEDM, 1982 by Teranishi et al. (N. Teranishi, A. Kohono, Y. Ishihara, E. Oda, and K. Rai, “No Image Lag Photodiode Structure in the Interline CCD Image Sensor,” in IEDM 1982, pp. 324-327), a pinning voltage higher than a gate turn-on voltage makes an operation of a transistor into a sub threshold region, and this results in image lag caused by incomplete reset and transfer process. Though such a noise element has a relatively constant value, as illumination decreases, a signal becomes weaker, and thereby signal vs. noise ratio (SNR) is drastically decreased in relatively low illumination. This results in degradation of image quality. Accordingly, the image lag has to be inhibited to protect degradation of the image quality in low illumination. This phenomenon more easily occurs in a junction profile which is not optimized. However, even if the junction profile is optimized, incomplete reset or incomplete charge depletion in an N well of a pinned photodiode occurs in some conditions, and thereby image lag is caused. As a result, up to recently, a doping condition of a photodiode, and particularly, design and processing conditions of a photodiode and a transfer transistor boundary are considered as crucial design parameters in an image pixel design.

Particularly, as a power supply voltage is more lowered for a low power operation, such a CMOS process and scaling of a device make these problems worse. The severest problem is incomplete charge depletion in the N well of the photodiode at a low operating voltage, for example, at 2.5V or less. For this reason, the image lag occurs, which results in deterioration of SNR at low illumination. Thus, recent technologies have focused on improving charge accumulation capabilities and developing a method for thoroughly resetting a photodiode in a low voltage operation.

To be specific, in the case of lowering the power supply voltage by scaling, though the pinned photodiode PPD may be completely depleted at 5V or 3.3V, in the conventional structure, the PDD may not be completely depleted when a rail voltage is 1.8V or 1.3V in a new integrated circuit process. This is because the transfer transistor is turned off before reaching the reset voltage of the photodiode, that is, a pinning voltage, or a reset voltage of the photodiode cannot be raised any more with entering a sub threshold region. Thus, such incomplete reset may be overcome by providing a lower threshold voltage of the transfer transistor, but thereby a well capacity of the PDD is reduced, and sufficient impedance may not be generated when the transfer transistor is turned off, which results in more decrease in the well capacity. In other words, if the threshold voltage of the transfer transistor is lowered in order to thoroughly and rapidly reset or transfer electrons, a sufficient barrier may not be formed when the transfer transistor is turned off, so that the well capacity decreases. On the other hand, if the threshold voltage of the transfer transistor is increased, a sufficient barrier is formed so that the well capacity may largely increase, but in this case, electrons are reset in the sub threshold region and then transferred, which results in incomplete depletion.

Another conventional art provided to overcome this problem is as follows.

The suggestion by Teranishi et al. (N. Teranishi, A. Kohono, Y. Ishihara, E. Oda, and K. Rai, “No Image Lag Photodiode Structure in the Interline CCD Image Sensor,” In IEDM 1982, pp. 324-327) is for completely depleting a photodiode before a transfer transistor is turned off by lowering a doping concentration of the photodiode. That is, an image lag effect is prevented by lowering the threshold voltage to completely deplete a photodiode before the transfer transistor is operated as a sub threshold region by an increased voltage of the photodiode. In addition, defects on a surface of the photodiode are suppressed as much as possible by implanting p+ into its surface, thereby reducing dark current. Thus, the image lag is suppressed, and deterioration of image quality may be prevented even at low illumination. However, this method cannot be continuously used at a low power supply voltage. This is because the photodiode is lightly doped, making it difficult to further lower a pinning voltage, and a voltage itself applied to the transfer transistor is already too low.

As still another method to overcome this problem, a method of operating a transfer transistor in a depletion mode by additionally doping a channel of the transfer transistor with an n-type dopant has been disclosed by Manabe in U.S. Patent Publication No. US2005/0017155 A1 entitled “Active Pixel Cell Using Negative to Positive Voltage Swing Transfer Transistor.” For example, if a threshold voltage is set as −0.7V, on and off states may be switched by voltage swing from −1.8V to +1.8V. In this method, a negative power source is required, which may be produced from a positive voltage by charge pumping in an integrated circuit. Here, even though a transfer transistor has the same gate voltages, a greater gate overdrive voltage is applied to the transistor by lowering threshold voltage, and thus a barrier between a photodiode and a transfer channel may be stably overcome to completely deplete the photodiode. Moreover, when the transfer transistor is off, holes may be accumulated in the channel, and thus dark current caused by a defect of the channel may be reduced depending on conditions. However, in the suggested structure, well capacity is not improved, and dark current may increase depending on actual realizations.

The severest problem caused by lowering an operating voltage is that a turn-on voltage of the transfer transistor is not higher enough than a threshold voltage of the transfer transistor, so that a photodiode moves to a sub threshold region before it is fully depleted. If the threshold voltage of the transistor is lowered, this problem may be solved, but if the transfer transistor is off, the transistor does not form a sufficient barrier, and thus a capacity of electrons which can be stored in the photodiode is reduced. As a result, the conventional arts described above cannot be appropriate solutions for overcoming the above problems because they may not improve well capacity and depletion efficiency at the same time.

Still another cause of dark current is shallow trench isolation (STI). The STI is a technology that is used for isolating devices or circuits from one another. To strengthen isolation performance of the STI, ions are injected into a silicon substrate in a region under a trench. However, the ion implantation into the region under the trench results in high leakage of current, which functions as dark current.

A method of reducing dark current that is generated in such STI is disclosed by micron (Korean Patent Publication No. 10-2005-0061608, entitled “Isolation Technology for Reducing Dark Current in CMOS Image Sensors”). In general, ions may be injected into a silicon substrate in a region under a trench for isolation in STI. However, as noted in a paper written by S. Nag et al. disclosed in IEEE IEDM, pp. 841-844 (1996), entitled “Comparative Evaluation of Gap-Fill Dielectrics in Shallow Trench Isolation for Sub 0.25 μm Technologies,” the ion injection under the trench may cause high leakage of current. In particular, when ions are injected into a substrate adjacent to edges of the trench, current leakage may occur in junctions between active device regions and the trenches.

### SUMMARY OF THE INVENTION

The present invention is directed to a transistor for an image sensor capable of completely depleting a photodiode in a low voltage operation, and an image sensor employing the same.

The present invention is also directed to a transistor for an image sensor capable of providing a sufficient barrier against a photodiode in an off state, and an image sensor employing the same.

The present invention is also directed to a transistor for an image sensor r capable of improving well capacity and depletion efficiency at the same time, and an image sensor employing the same.

The present invention is also directed to a transistor for an image sensor capable of suppressing generation of dark current, and an image sensor employing the same.

The present invention is also directed to a transistor for an image sensor which can reduce dark current generated by STI, and an image sensor employing the same.

One aspect of the present invention provides a transistor for an image sensor comprising: a main gate oxide disposed on a charge transfer channel from a photodiode to a diffusion node; a main gate electrode disposed on the main gate oxide; a sub gate oxide disposed to overlap a part of the photodiode; and a sub gate electrode extending from the main gate electrode and disposed on the sub-gate oxide.

Another aspect of the present invention provides an image sensor, comprising: a photosensitive pixel having a transfer transistor formed in a structure which causes hole accumulation in a part or all regions of a gate oxide; and a sensing control part applying a negative offset potential to the gate during a part or whole of a turn-off period of the transfer transistor.

Yet another aspect of the present invention provides an image sensor, comprising: a photodiode; a transistor for an image sensor for moving a charge of the photodiode; and a dark current removal electrode electrically connected with a gate electrode of the transistor for an image sensor, and insulated from and overlapping a region in which a dark current is generated.

In the present invention, three improvements are presented to enhance a performance of an image sensor due to dark current reduction and so forth.

First, in a light integration region, a region of a photodiode to which light is applied, a negative offset potential is applied to a transfer transistor or another transistor corresponding to the transfer transistor, thereby raising a barrier and improving well capacity, and a trap disposed around the transistor is deactivated by holes accumulated around the transistor, and thus the dark current is reduced. Since the hole accumulation is achieved by negative offset bias rather than p type doping, transfer transistor should have low threshold voltage. As a result, complete photodiode reset may be performed by a structure capable of using a high overdrive voltage (that is, the transfer transistor transfers enough charges). Also, when the photodiode is reset, the photodiode is depleted at a low voltage and then the barrier is raised by an external terminal so as to reset the transistor, and thus the efficiency of the well capacity may increase when the transistor is reset.

Second, a sub gate oxide for forming the transfer transistor is included to maximize the application of the negative offset potential according to the first aspect, and is disposed to overlap a part of a light receiving part of the photodiode.

Third, the dark current caused by a trench region is reduced by limiting reception of light around the trench region of the light receiving part of the photodiode.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a circuit diagram illustrating a structure of a 4-transistor image sensor;

FIG. 2 is a cross-sectional view of a stack structure around a transfer transistor in an image sensor according to conventional art;

FIG. 3 is a cross-sectional view of a stack structure around a transfer transistor in an image sensor according to an exemplary embodiment of the present invention;

FIG. 4 illustrates waveforms of a switching signal applied to a transfer transistor gate according to an exemplary embodiment of the present invention;

FIG. 5 is a cross-sectional view of a stack structure around a transfer transistor in an image sensor according to another exemplary embodiment of the present invention;

FIG. 6 is a plan view of a layout structure of an image sensor according to still another exemplary embodiment of the present invention; and

FIG. 7 is a circuit diagram illustrating a structure of a CMOS image sensor according to an exemplary embodiment of the present invention.

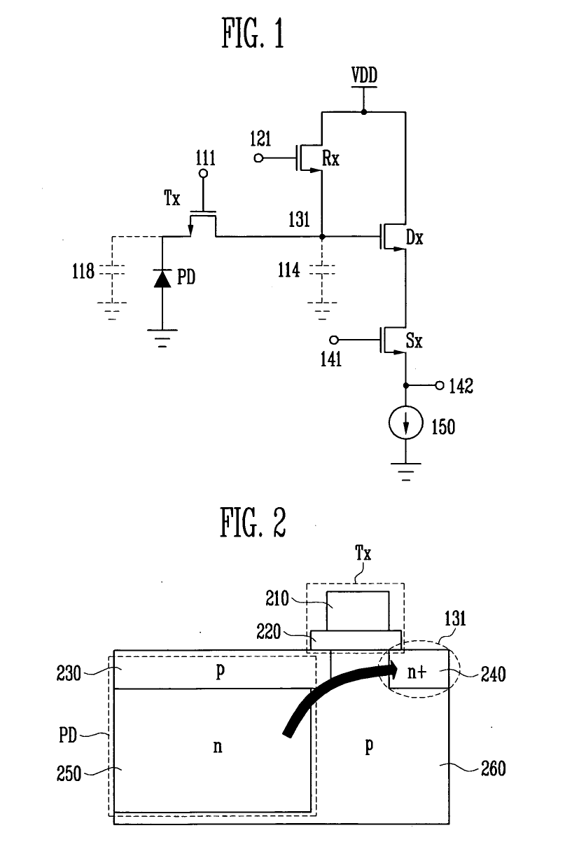

### DETAILED DESCRIPTION OF EXEMPLARY EMBODIMENTS

Hereinafter, exemplary embodiments of the present invention will be described in detail. However, the present invention is not limited to the exemplary embodiments disclosed below, but can be implemented in various types. Therefore, the present exemplary embodiments are provided for complete disclosure of the present invention and to fully inform the scope of the present invention to those ordinarily skilled in the art.

### Exemplary Embodiment 1

FIG. 3 is a cross-sectional view of a 4-transistor pixel structure according to an exemplary embodiment of the present invention. Though the exemplary embodiment specifically describes the aspect of the present invention is applied to a transfer transistor, this is only an example for convenience of descriptions because a transfer transistor has the highest efficiency. Thus, it is apparent that the aspect of the invention may also be applied to other transistor devices in an image sensor (particularly, a reset transistor with a function of transferring charges), which is also in the scope of the present invention.

FIG. 3 only illustrates a photodiode PD, a transfer transistor Tx and a floating diffusion region 131 in the 4-transistor pixel structure. The transfer transistor Tx comprises a gate 310, a gate oxide layer 320 and a p-type substrate 360, the photodiode PD region comprises a photodiode (n-type) doped region 350 and a surface p-doped region 330, and the diffusion node 340 is an n⁺ diffusion node. Here, a p-doped region 332 adjacent to the transfer transistor is formed adjacent to the surface p-doped region 330, and in the exemplary embodiment, a performance of an image sensor is improved by accumulating holes in the p-doped region 332.

The performance improvement by the hole accumulation will now be described in detail. At first, a period in which light is applied to the photodiode during a turn-off period of the transfer transistor in the 4-transistor pixel structure is defined as an integration period.

In the integration period, a predetermined negative offset potential is applied to the gate 310 of the transfer transistor so as to accumulate holes in the p-doped region 332 adjacent to the transfer transistor through the gate oxide layer 320. In this case, a trap is deactivated in the p-doped region 332 adjacent to the transfer transistor, so that electron-hole pairs and thus dark current are reduced. In addition, the voltage applied to the gate 310 in the period when the transfer transistor is off raises a potential barrier under the gate oxide layer 320, thereby increasing well capacity of electrons which can be accumulated in the photodiode.

There may be several methods of fabricating a transfer transistor having the illustrated structure, and among these, a fabrication method which may minimize modifications of a conventional image sensor fabrication process is as follows. In a typical photodiode, the p-type layer 330 is formed by forming the gate oxide layer and then implanting a p-type dopant material such as boron into the gate oxide layer. Here, the implanted dopant material at an interface is partially diffused down to the gate oxide layer by a subsequent thermal treatment process. The conventional art tries to minimize the diffusion of the dopant material, but in the exemplary embodiment, the diffusion of the dopant material is maximized to form the p-type region 332 overlapping the gate electrode 310. That is, the region 332 overlapping the gate electrode 310 of the two p-type layers 330 and 332 in the photodiode is formed by horizontal diffusion of the dopant material.

In another method of fabricating the transfer transistor according to the exemplary embodiment, the p-type region 332 overlapping the gate electrode 310 may be formed to be integral with or separated from the original p-type region 330 of the photodiode through a separate lithography process and a subsequent stacking process before the gate electrode 320 is formed.

When the p-doped region 332 is formed to be separated from the original p-type region 330, the p-doped region 332 is doped in a different pattern from the surface p-doped region of the photodiode. The surface p-doped region of the photodiode is generally formed by somewhat complex doping, for example, double or more doping for photosensitivity and/or reset efficiency. Since the p-doped region 332 according to the present invention is for improving hole accumulation and charge transfer efficiencies, the doping is preferably performed therefor. Accordingly, the p-doped region 332 may not be double-doped and formed to be as thin as the surface p-type region 230. The latter may maximize a trap removal effect by the p-doped region 332 under the gate oxide layer 320.

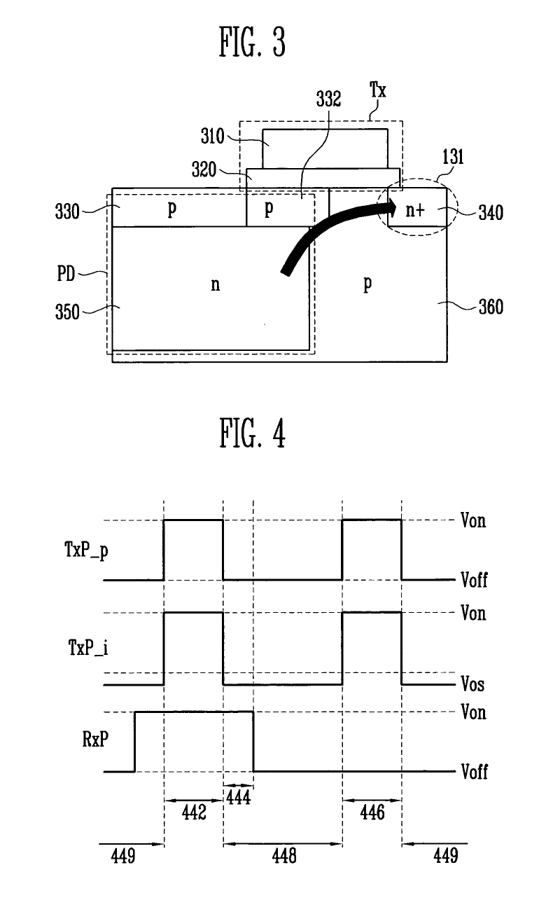

When a switching signal which is the same as the conventional art is applied to a gate of a transfer transistor having the same structure above, the improved effect of the present invention above does not appear. An example of a switching signal waveform for obtaining the improved effect of the transfer transistor is illustrated in FIG. 4. For convenience of understanding, such a switching signal waveform is shown with a conventional switching signal waveform in FIG. 4

Conventional signals TxP_p and RxP applied to a gate of a transfer transistor and a reset transistor, respectively, have a power potential Von and a ground potential Voff. A temporal period of the signals is divided into a photodiode reset period 442, a diffusion node reset period 444, an electron accumulation period by photon (integration period, 448), and a period 446 in which electrons accumulated in a photodiode are moved to a diffusion node. The temporal period of the signals further includes a read period 449 in which several pixels are sequentially read out. The read period 449 is generally shorter than the electron accumulation period by photon 448.

With the waveform of the switching signal for implementing the present invention, the negative offset potential Vos, not the ground potential Voff, is applied to the gate of the transfer transistor in the electron accumulation period by photon 448. In FIG. 4, the same offset potential Vos is applied in the read period 449, but other potential such as the ground potential Voff may be applied thereto depending on embodiments. For optimal performance, the negative offset potential is determined as a point between about −0.1V to −1.0V at which the inactivity of a trap is the most excellent.

The present invention requires the negative offset potential having a smaller absolute value than the power potential, which simplifies the structure of a circuit for generating such an offset potential.

The modified switching signal waveform according to a first aspect of the present invention may be applied not only to the transfer transistor of the first exemplary embodiment, but also to a transfer transistor of a second exemplary embodiment that will be described below. The modified switching signal waveform may also be applied to other transfer transistors having a p-type region under a gate electrode.

### Exemplary Embodiment 2

The exemplary embodiment relates to a transfer transistor having an optimized stack structure for the control method for the transfer transistor illustrated in FIG. 4. Though the exemplary embodiment specifically describes the aspect of the present invention is applied to a transfer transistor, this is only an example for convenience of descriptions because a transfer transistor has the highest efficiency. Thus, it is apparent that the aspect of the invention may also be applied to other transistor devices in an image sensor (particularly, a reset transistor with a function of charge transfer), which is also in the scope of the present invention.

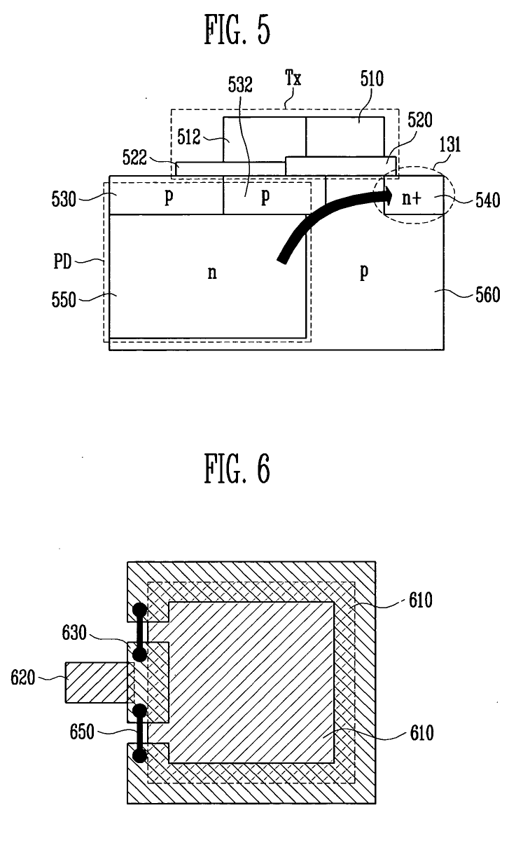

A transfer transistor illustrated in FIG. 5 includes a main gate oxide 520 disposed on a charge transfer channel from a photodiode to a diffusion node; a main gate electrode 510 disposed on the main gate oxide 520; a sub gate oxide 522 extending from the main gate oxide 520 and overlapping a part of the photodiode; and a sub gate electrode 512 extending from the main gate electrode 510 and disposed on the sub gate oxide 522.

As in the first exemplary embodiment of FIG. 3, the transfer transistor comprises a gate 510, a gate oxide layer 520 and a p-type substrate 560. And, the photodiode region comprises a photodiode doped region 550 and a surface p-doped region 530, and the diffusion node is an n+ doped diffusion node 540. In addition, a p-doped region 532 adjacent to the transfer transistor is formed adjacent to the surface p-doped region 530. The exemplary embodiment may include the sub gate oxide 522 which is a thin oxide layer to well accumulate holes in the p-doped region 532 adjacent to the transfer transistor, and have an offset potential close to 0V, which will be applied to the main gate electrode 510. The sub gate oxide 522 which is a thin oxide layer has high transparency with respect to light, and thus may effectively transfer light into the photodiode region which is covered with the sub gate oxide 522.

The sub gate electrode 512 which is adjacent or connected to the gate electrode 510 of the transfer transistor may be formed of the same material as the gate electrode 510, however, it is preferably formed of a conductive material such as a transparent electrode material, for example, ITO, to absorb a photon in the photodiode doped region 550 under the separate gate electrode 512, and thus the sensitivity to light may be relatively enhanced.

In fabrication of the transfer transistor of the present exemplary embodiment, while the two surface p-doped regions 530 and 532 are separately formed to maximize trap removal by the p-doped region 532 disposed under the gate oxide layer, the two surface p-doped regions 530 and 532 may be formed to be integral with each other by the almost same method as the conventional art for fabrication efficiency. The sub gate oxide 522 and the sub gate electrode 512 may be fabricated by a lithography process and a subsequent stacking process.

After the 4-transistor CMOS image sensor with the transfer transistor according to the exemplary embodiment is implemented, a switching signal having the same waveform as the first exemplary embodiment illustrated in FIG. 4 is applied to the gate, and an operation of the image sensor is the same as the first exemplary embodiment. Thus, detailed descriptions will be omitted.

### Exemplary Embodiment 3

The present exemplary embodiment relates to an image sensor having an optimal structure for suppressing dark current according to a third aspect of the present invention. Here, the image sensor may be modified entirely or partially.

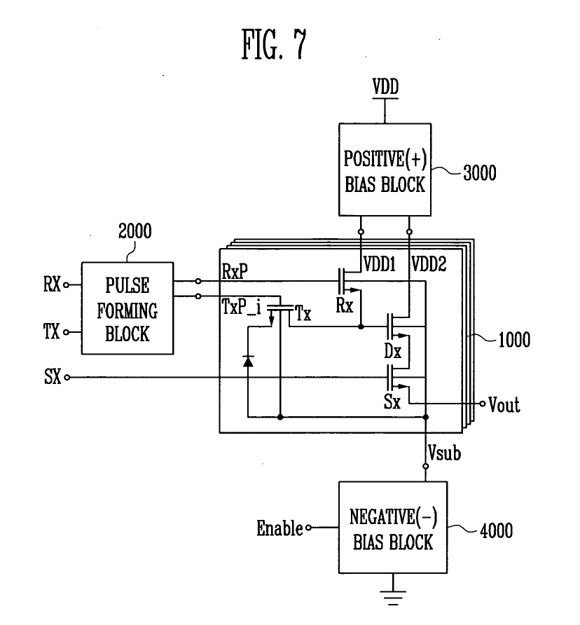

The image sensor illustrated in FIG. 6 includes: a diffusion node region 620; a photodiode region 610; a transfer transistor for forming a charge transfer channel between the diffusion node and the photodiode; and a dark current removal electrode 640 electrically connected with a gate electrode 630 of the transfer transistor, and insulated from a part of the photodiode region in which dark current is generated and overlapping the part.

The dark current removal electrode 640 may be a transparent electrode, for example, formed of ITO, to increase photon absorbing efficiency in the photodiode region 610 under the dark current removal electrode 640, and form an oxide layer under the photodiode region 610 to ensure an electrically insulated state from the overlapped photodiode region 610.

The transfer transistor is formed between the diffusion node 620 and the photodiode region 610. The additional electrode 640 connected with the gate electrode 630 of the transfer transistor may be formed to increase well capacity or be connected to a part having dark current to be reduced. Here, the dark current removal electrode 640 is formed to cover an edge of the photodiode, and connected with the gate electrode 630 with a connection line 650. In addition, another removal electrode may be formed in a peripheral region in which the dark current may occur. Particularly, in the case of the image sensor in FIG. 5, the additional gate electrode 522 may function as the dark current removal electrode 640 of FIG. 6.

To be specific, the removal electrode is formed on a shallow trench isolation (STI) region of the image sensor, thereby effectively reducing the dark current. Such an image sensor may effectively prevent generation of the dark current by the dark current removal electrode 640, and allow a part under the trench to be highly doped. The high doping under the trench helps isolation, and thus further raises storing efficiency of electrons (well capacity) in a CMOS image sensor. Further, when a filling including silicon is used, a trench may be deeper than 2000 to 2500 A compared when the filling is not used, so as to reduce high crosstalk isolation.

The dark current removal electrode 640 and the underlying oxide layer may be fabricated by a lithography process and a subsequent stacking process. Further, after the 4-transistor CMOS image sensor with the transfer transistor of the exemplary embodiment is implemented, a switching signal (TxP_i) having the same voltage waveform as the first exemplary embodiment illustrated in FIG. 4 is applied to a gate, and an operation of the image sensor is the same as in the first exemplary embodiment, so detailed descriptions about this will be omitted.

The improvements of the image sensor of the first and second exemplary embodiments are compatible with the improvement of the third exemplary embodiment, so formation of an image sensor according to the first and third exemplary embodiments or an image sensor according to the second and third exemplary embodiments may be easily derived from the above descriptions, and thus the detailed description about this will be omitted.

However, it is to be noted that when the exemplary embodiment employs the transfer transistor according to the first and second exemplary embodiments, and a switching signal which is the same as TxP_p of FIG. 4 is applied to the gate electrode in the transfer transistor, applications of negative offset potential in the 449 and 448 periods bring the deactivation of the trap according to the first and second exemplary embodiment, and further increase dark current removal effect of the dark current removal electrode 640.

FIG. 7 illustrates a structure of an image sensor including a photosensitive pixel and a related control block for performing the sensing control method illustrated in FIG. 4. Among illustrated components, a sensing control part according to the present exemplary embodiment is a pulse forming block 2000.

The pulse forming block 2000 receives RX and TX signals as applied to a conventional image sensor, and generates TxP_i and RxP signals as illustrated in FIG. 4, and thereby giving negative offset to a turn-off voltage applied to a gate of the transfer transistor.

As described above, with an image sensor, the generation of dark current in a photodiode can be suppressed, and the influence of dark electrons in a transient period of a peripheral transistor of the photodiode, for example, a transfer transistor of the CMOS image sensor can be suppressed. Thus, the maximum characteristics of the image sensor can be utilized.

That is, when the transfer transistor is turned off, a sufficient barrier is formed so that electrons can be accumulated in the photodiode, and when the transistor is on, the barrier is sufficiently lowered so that the photodiode is fully depleted before the transfer transistor reaches the threshold voltage.

Particularly, an expression that a sufficient barrier is formed by applying a negative voltage to a TX transistor in an off state indicates the increase in well capacity. The well capacity can be reduced due to a reduced barrier under the TX transistor in light of a structure of device design and process. However, in this case, the reduced well capacity may be increased again by applying the negative voltage to the transistor.

Moreover, a trap in a predetermined region is deactivated for a certain time, which results in reduction of the dark current.

And, a fill factor, the most important factor of the image sensor, may not be reduced by using a conventional transistor without adding another transistor, for example, the transfer transistor in the CMOS image sensor comprising four transistors, as a gate necessary for accumulation, and thus the dark current is reduced and the well capacity is increased while retaining other optical characteristics.

For more excellent optical characteristics, a separate transistor (or a MOS capacitor) is disposed in a photo sensing part, i.e., around the photodiode of the CMOS image sensor and then a signal is applied thereto. Here, the gate may have a structure which can facilitate accumulation on a silicon surface.

In the case of using a conventional transistor or an additional structure, an applied signal is used together with a signal on the transfer transistor gate, thereby eliminating a need of changing a drive address interconnection of pixels and allowing the use of the same height and area as in a conventional structure.

The pixel characteristic may be enhanced by using a transfer transistor having a lower threshold voltage by reducing channel doping of the transfer transistor.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A transistor for an image sensor, comprising:
a main gate oxide disposed on a charge transfer channel from a photodiode to a diffusion node;
a main gate electrode disposed on the main gate oxide;
a sub gate oxide disposed to overlap a part of the photodiode; and
a sub gate electrode extending from the main gate electrode and disposed on the sub-gate oxide.

2. The transistor of claim 1, wherein the sub gate oxide extends from the main gate oxide.

3. The transistor of claim 1, wherein the sub gate oxide is thinner than the main gate oxide.

4. The transistor of claim 1, wherein the sub gate electrode is formed of a transparent conductive material.

5. The transistor of claim 1, wherein the sub gate electrode is insulated from and overlaps a part of the photodiode region in which a dark current is generated, and comprises a dark current removal electrode.

6. The transistor of claim 1, wherein a part of the channel under the gate oxide has a different concentration therefrom.

7. The transistor of claim 6, wherein the part of the channel with the different concentration is formed by diffusing a dopant material forming a p-type layer constituting the photodiode.

8. An image sensor, comprising:
a photosensitive pixel having a transfer transistor formed in a structure which causes hole accumulation in a part or all regions of a gate oxide; and
a sensing control part applying a negative offset potential to the gate during a part or whole of a turn-off period of the transfer transistor.

9. The image sensor of claim 8, wherein a part of a gate electrode of the transfer transistor overlaps a part of a p-type layer constituting a photodiode.

10. The image sensor of claim 9, wherein the region of the p-type layer of the photodiode overlapping the gate electrode is formed by diffusing a dopant material forming a non-overlapped region of the p-type layer of the photodiode.

11. The image sensor of claim 8, wherein the sensing control part applies a negative offset potential to the gate of the transfer transistor during an integration period of the photosensitive pixel.

12. The image sensor of claim 11, wherein the negative offset potential has a level between −0.1V and −1.0V.

13. The image sensor of claim 8, wherein the transfer transistor is a transistor of claim 1.

14. An image sensor, comprising:
a photodiode;
a transistor for an image sensor for moving a charge of the photodiode; and
a dark current removal electrode electrically connected with a gate electrode of the transistor for an image sensor, and insulated from and overlapping a region in which a dark current is generated.

15. The image sensor of claim 14, wherein the dark current removal electrode is formed at an edge part of the photodiode.

16. The image sensor of claim 14, wherein the dark current removal electrode is formed around a shallow trench isolation (STI) region.

17. The image sensor of claim 14, wherein the dark current removal electrode is formed of a transparent conductive material.

18. The image sensor of claim 14, wherein the transistor for an image sensor is a transistor of claim 1.
